(19) United States
(12) Patent Application Publication
(10) Pub. No.: US 2024/0329528 A1
(43) Pub. Date: Oct. 3, 2024

(54) PHOTOSENSITIVE PASTE

(71) Applicant: Murata Manufacturing Co., Ltd., Kyoto-fu (JP)

(72) Inventor: Isamu MIYAKE, Nagaokakyo-shi (JP)

(73) Assignee: Murata Manufacturing Co., Ltd., Kyoto-fu (JP)

(21) Appl. No.: 18/434,550

(22) Filed: Feb. 6, 2024

(30) Foreign Application Priority Data
Mar. 2, 2023 (JP) 2023-031819

(51) Int. Cl. G03F 7/031; C08K 3/08; H01F 17/00; H01F 41/04

(52) U.S. Cl. CPC G03F 7/031; C08K 3/08; H01F 17/0013; H01F 41/045; C08K 2003/0806; C08K 2201/001; C08K 2201/005

(57) ABSTRACT

A photosensitive paste contains an inorganic powder, a photopolymerizable monomer, an alkali-soluble polymer, and an oxime ester initiator having a diphenyl sulfide group.

### CROSS-REFERENCE TO RELATED APPLICATION

This application claims benefit of priority to Japanese Patent Application No. 2023-031819, filed Mar. 2, 2023, the entire content of which is incorporated herein by reference.

### BACKGROUND

### Technical Field

The present disclosure relates to a photosensitive paste.

### Background Art

In the related art, oxime ester compounds have been used as high-shielding polymerization initiators in photosensitive pastes. For example, in Japanese Unexamined Patent Application Publication No. 2017-182901, a photosensitive paste is described that contains an inorganic powder, a photopolymerizable monomer, an alkali-soluble polymer, and a photosensitizer such as an oxime ester initiator.

### SUMMARY

Incidentally, the formation of a wiring pattern, the formation of a wiring pattern with a large thickness in particular, by irradiating an oxime ester initiator-containing photosensitive paste as described in the related art with active energy radiation, such as ultraviolet radiation, has caused the width of the wiring pattern to be broad as well. This is believed to be because not only the active energy radiation spreads in the direction of active irradiation, but also the active energy radiation spreads in the direction perpendicular to the direction of irradiation, and, as a result, the width of the wiring pattern expands.

Therefore, the present disclosure provides a photosensitive paste with which when development is performed after irradiation with active energy radiation with an interposed photomask, the width of the resulting wiring pattern is close to that of the photomask.

Accordingly, an aspect of the present disclosure provides a photosensitive paste containing an inorganic powder; a photopolymerizable monomer; an alkali-soluble polymer; and an oxime ester initiator having a diphenyl sulfide group.

By virtue of having this aspect, the present disclosure is able to provide a photosensitive paste with which while the spread of active energy radiation in the direction perpendicular to the direction of irradiation with the energy radiation can be reduced, free radicals with a great spread of the active energy radiation in the direction of irradiation can be formed.

A method that is an aspect of the present disclosure for forming a wiring pattern includes a step of applying the above photosensitive paste that has conductivity onto an insulating sheet to form a photosensitive paste film; a step of irradiating part of the photosensitive paste film with active energy radiation; and a step of removing an uncured portion of the photosensitive paste film to form a wiring pattern.

According to this embodiment, a wiring pattern having the desired shape is obtained.

A method that is an aspect of the present disclosure for manufacturing an electronic component includes a step of applying the above photosensitive paste that has conductivity onto an insulating sheet to form a photosensitive paste film; a step of irradiating part of the photosensitive paste film with active energy radiation; a step of removing an uncured portion of the photosensitive paste film to form a wiring pattern; a step of placing an insulating sheet on the wiring pattern; and a step of firing the wiring pattern and the insulating sheets to obtain multiple insulating layers as a sintered form of the multiple insulating sheets and inner wiring as a sintered form of the wiring pattern.

According to this embodiment, an electronic component having high-accuracy inner wiring is obtained.

An electronic component that is an aspect of the present disclosure includes a body including multiple insulating layers; and inner wiring disposed inside the body as a sintered form of the photosensitive paste according to the present disclosure that has been cured.

According to this embodiment, an electronic component superior in performance and reliability is obtained.

According to the present disclosure, there can be provided a photosensitive paste with which when development is performed after irradiation with active energy radiation with an interposed photomask, the width of the resulting wiring pattern is close to that of the photomask.

### BRIEF DESCRIPTION OF THE DRAWINGS

FIG. 1 is a transparent perspective view schematically illustrating an inductor component;

FIG. 2 is an exploded perspective view schematically illustrating an inductor component;

FIG. 3A is an XZ cross-sectional view schematically illustrating a method for measuring width L μm; and

FIG. 3B is an XZ cross-sectional view schematically illustrating a method for measuring width L μm.

### DETAILED DESCRIPTION

A photosensitive paste, a method for forming a wiring pattern, a method for manufacturing an electronic component, and an electronic component that are aspects of the present disclosure will now be described in detail with embodiments illustrated in the drawings. It should be noted that some of the drawings are schematic; the dimensions and proportions may be different from reality.

In the following, an inductor component 10 will be described as an electronic component. The electronic component, however, may be a different component, such as one of various electronic components including capacitor components and LC components.

### First Embodiment

### Inductor Component

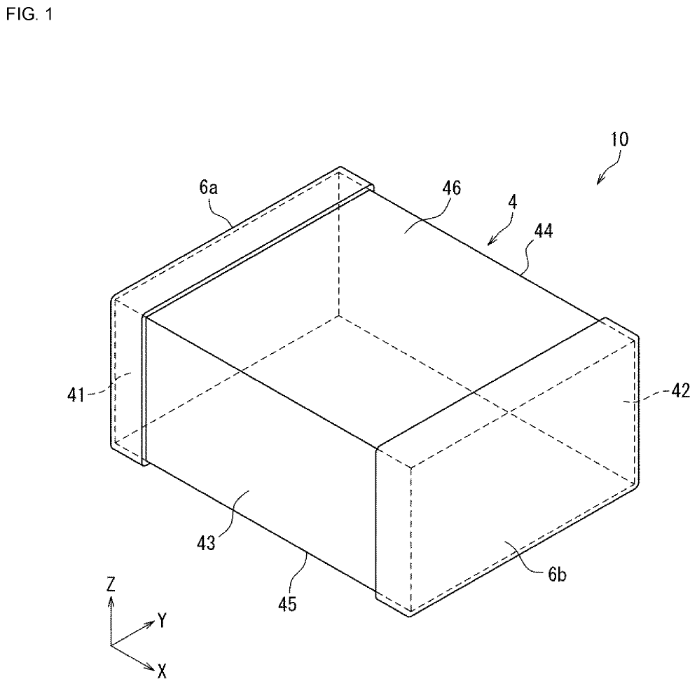

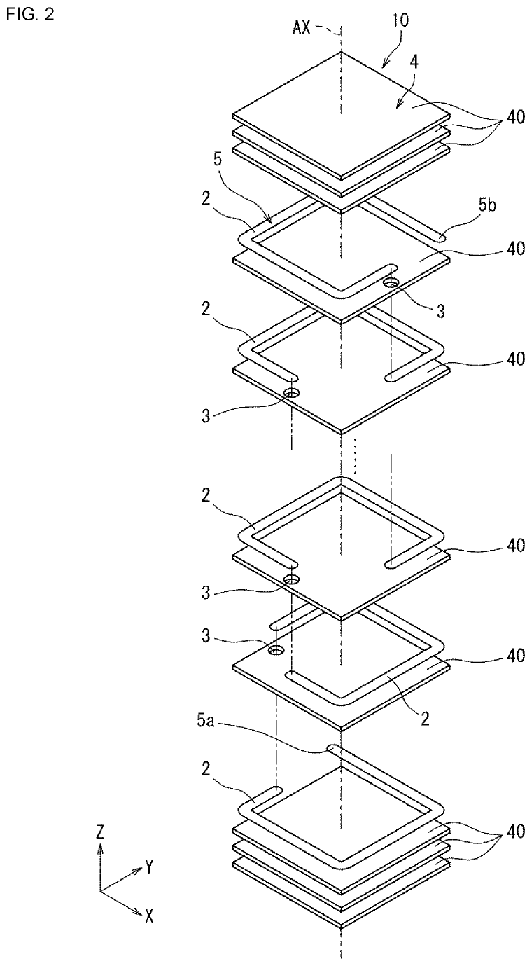

FIG. 1 is a transparent perspective view schematically illustrating the inductor component 10. FIG. 2 is an exploded perspective view schematically illustrating the inductor component 10. Although the body 4 in FIG. 1 is depicted as transparent so that the structure can be easily understood, the body 4 may be translucent or opaque. In FIG. 1, the description of a coil 5 is omitted so that the structure can be easily understood. In FIG. 2, the description of outer electrodes is omitted considering visual clarity.

As illustrated in FIGS. 1 and 2, the inductor component 10 includes a body 4, a coil 5 disposed inside the body 4, and a first outer electrode 6a and a second outer electrode 6b disposed on the body 4.

The shape of the body 4 is not particularly limited. In this embodiment, the body 4 is substantially cuboid in shape. The outer surface of the body 4 has a first end face 41, a second end face 42 facing the first end face 41, a first side face 43 connecting the first end face 41 and the second end face 42 together, a second end face 44 facing the first side face 43, a bottom face 45 connecting the first end face 41, the second end face 42, the first side face 43, and the second side face 44 together, and a top face 46 facing the bottom face 45 and connecting the first end face 41, the second end face 42, the first side face 43, and the second side face 44. The direction from the first end face 41 toward the second end face 42 is defined as the X direction, the direction from the first side face 43 toward the second side face 44 is defined as the Y direction, and the direction from the bottom face 45 toward the top face 46 is defined as the Z direction. Herein, the Z direction may be referred to as the upper side.

The body 4 is composed of multiple insulating layers 40 stacked on top of each other. The insulating layers 40 correspond to an example of a sintered form of the “insulating sheets” in the claims. The material for the insulating sheets is not particularly limited. For example, the insulating sheets are made of a borosilicate glass-based material or a material such as ferrite or a resin. The direction of stacking of the insulating layers 40 is parallel to the Z direction. In other words, the insulating layers 40 are in the shape of layers extending in the XY plane. “Parallel” is not limited to a strictly parallel relationship and includes relationships that are substantially parallel considering a realistic range of variations. The interfaces between the multiple insulating layers 40 in the body 4 may be unclear, for example as a result of firing.

The coil 5 has multiple coil wires 2 stacked along the direction of an axis AX and via wires, not illustrated, extending along the direction of the axis AX and coupling together coil wires 2 adjacent to each other in the direction of the axis AX. The multiple coil wires 2 form a spiral while each of them is turned along a plane, positioned next to another in the direction of the axis AX, and electrically coupled to the others in series. The coil wires 2 are formed using a photosensitive paste that is conductive (photosensitive conductive paste). The coil wires 2 correspond to an example of the “inner wiring” in the claims. The coil wires 2 and the “inner wiring” correspond to examples of the “wiring pattern” or a sintered form of the “photosensitive paste” having conductivity and cured in the claims.

The coil 5 is formed rectangular as viewed in the direction of the axis AX but is not limited to this shape. The shape of the coil 5 may be, for example, round, oval, rectangular, or other polygonal shapes. The direction of the axis AX of the coil 5, furthermore, is parallel to the Z direction, and the coil 5 is wound along the direction of the axis AX. The axis AX of the coil 5 represents the central axis of the spiral shape of the coil 5.

The coil 5 is wound in a spiral shape along the direction of stacking of the insulating layers 40. A first end 5a of the coil 5 is exposed from the first end face 41 of the body 4 and coupled to the first external electrode 6a. A second end 5b of the coil 5 is exposed from the second end face 42 of the body 4 and coupled to the second external electrode 6b.

The coil wires 2 are formed by being turned on a main surface (XY plane), which is perpendicular to the direction of the axis AX, of the insulating layers 40. The number of windings in the coil wires 2 is less than one loop but may be one or more loops. The via wires are located inside via holes 3 in the insulating layers 40 and extend through the insulating layers 40 in the thickness direction (Z direction). Coil wires 2 adjacent in the direction of stacking, furthermore, are electrically coupled in series with a via wire interposed therebetween.

An insulating layer 40 located between adjacent coil wires 2 has a via hole 3 at the position at which the adjacent coil wires 2 are coupled together. The via hole 3 extends through the insulating layer 40 in the thickness direction (Z direction).

The first outer electrode 6a and the second outer electrode 6b are composed of a conductive material, such as Ag, Cu, or Au or an alloy based on such a metal. In this embodiment, the first outer electrode 6a is disposed continuously over the entire first end face 41 of the body 4, an end portion of the first side face 43 closer to the first end face 41, an end portion of the second side face 44 closer to the first end face 41, an end portion of the bottom face 45 closer to the first end face 41, and an end portion of the top face 46 closer to the first end face 41. The second outer electrode 6b, furthermore, is disposed continuously over the entire second end face 42 of the body 4, an end portion of the first side face 43 closer to the second end face 42, an end portion of the second side face 44 closer to the second end face 42, an end portion of the bottom face 45 closer to the second end face 42, and an end portion of the top face 46 closer to the second end face 42. In short, each of the first and second outer electrodes 6a and 6b is a five-sided electrode. This, however, is not the only possible structure; the first outer electrode 6a may be, for example, an L-shaped electrode disposed continuously over part of the first end face 41 and part of the bottom face 45. Likewise, the second outer electrode 6b may be, for example, an L-shaped electrode disposed continuously over part of the second end face 42 and part of the bottom face 45.

As described above, an inductor component 10 having high-accuracy inner wiring is obtained.

### Photosensitive Paste

The detailed composition of the photosensitive paste used for the formation of the coil 5 will now be described.

A photosensitive paste according to the present disclosure contains an inorganic powder, an oxime ester initiator having a diphenyl sulfide group (-Ph-S-Ph- group), a photopolymerizable monomer, and an alkali-soluble polymer. It should be noted that Ph represents a phenyl group. The photosensitive paste according to the present disclosure is of the negative type, containing a photopolymerizable monomer that polymerizes in response to active energy radiation. The component of the photosensitive paste excluding the inorganic powder therefrom may be hereinafter referred to as the photosensitive resin composition. A composition containing the photopolymerizable monomer, the alkali-soluble polymer, and the oxime ester initiator having a diphenyl sulfide group may be referred to as the first composition.

### Inorganic Powder

The inorganic powder has a conductive powder. It should be noted that the inorganic powder may be nonconductive. For example, it may be glass powder or ceramic powder.

Examples of inorganic powders include silver (Ag), copper (Cu), gold (Au), platinum (Pt), lead (Pd), nickel (Ni), tungsten (W), aluminum (Al), and molybdenum (Mo). One of these is used alone, or two or more are used in combination.

The inorganic powder preferably has Ag.

Preferably, the D50 of the Ag is 5.0 μm or less. By having this configuration, the Ag is easy to be packed when the photosensitive paste is applied, allowing the density of the Ag to be large. As a result, the resistance value of coil wire layers 2 formed from the photosensitive paste is reduced. The lower limit of the D50 of the Ag is not particularly limited, but for example, it is 0.4 μm. The D50 of the Ag may be 4.0 μm or less.

It should be noted that D50 is a volume-based median and is obtained from a particle size distribution in the range of 0.02 μm to 1,400 μm determined by laser diffraction/scattering using a particle size distribution analyzer (e.g., MT3300-EX, manufactured by BELMicrotrac Corp.).

The amount of the inorganic powder in relation to the first composition may be 170% by mass or more and may be 300% by mass or more. The amount of the inorganic powder in relation to the first composition may be 1700% by mass or less and may be 1000% by mass or less. In one aspect, the amount of the inorganic powder in relation to the first composition may be 170% by mass or more and 1700% by mass or less (i.e., from 170% by mass to 1700% by mass) and may be 300% by mass or more and 1000% by mass or less (i.e., from 300% by mass to 1000% by mass).

In one aspect, the amount of the inorganic powder in relation to the photosensitive paste may be 50% by mass or more and may be 60% by mass or more. The amount of the inorganic powder in relation to the photosensitive paste may be 95% by mass or less and may be 90% by mass or less. In one aspect, the amount of the inorganic powder in relation to the photosensitive paste may be 50% by mass or more and 95% by mass or less (i.e., from 50% by mass to 95% by mass) and may be 60% by mass or more and 90% by mass or less (i.e., from 60% by mass to 90% by mass).

### First Composition

### Oxime Ester Initiator Having a Diphenyl Sulfide Group

By virtue of the use of an oxime ester initiator, the active energy radiation, such as ultraviolet radiation, spreads in the direction of irradiation with the active energy radiation. As a result of this, the curability of the photosensitive paste is enhanced. When an insulating layer with a photosensitive paste film formed thereon through the application of the photosensitive paste to the insulating layer is irradiated with vertical active energy radiation from the photosensitive paste film side, furthermore, the spread of the active energy radiation in the direction perpendicular to the direction of irradiation is reduced. The inventors believe that this is because by virtue of the presence of a diphenyl sulfide group in the oxime ester initiator, the transmittance of the active energy radiation in the direction of irradiation is increased while the transmittance of the active energy radiation in the direction perpendicular to the direction of irradiation is reduced. As a result of this, a sufficient thickness, in the direction of irradiation with the active energy radiation, of the cured portion of the photosensitive paste is ensured, and the spread of the width, in the direction perpendicular to the direction of irradiation with the active energy radiation, of the cured portion is reduced at the same time. In other words, the inventors believe that the diphenyl sulfide group is a group that increases photobleachability. By virtue of having photobleachability, the initiator is able to increase absorbance in the direction perpendicular to the direction of irradiation with the active energy radiation while reducing absorbance in the direction of irradiation. With the use of an oxime ester initiator having a diphenyl sulfide group is used, therefore, the active energy radiation can be controlled so that it will penetrate through the paste in the direction of irradiation and not in the direction perpendicular to the direction of irradiation.

The oxime ester initiator having a diphenyl sulfide group has an ═N—O—CO—R¹ group. In this context, R¹ is an alkyl group with one or more and three or fewer carbons. By virtue of having this structure, the ═N—O—CO—R¹ group undergoes the breakage of a bond between the N atom and the O atom, and then carbon dioxide (CO₂) departs from the —O—CO—R¹ group. As a result of this, free radicals R¹ with high mobility are formed.

The oxime ester initiator having a diphenyl sulfide group is represented by formula (1).

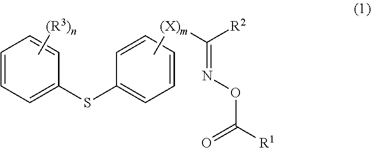

In formula (1), R¹ is an alkyl group with one or more and three or fewer carbon atoms. R² is a monovalent organic group. Each R³ is independently a monovalent organic group. Each X is independently a divalent organic group. m is an integer of 1 or greater and 5 or smaller (i.e., from 1 to 5). n is an integer of 0 or greater and 5 or smaller (i.e., from 0 to 5). As used herein, organic group refers to a group containing a carbon atom. An organic group is not particularly limited, but it may contain one or more nitrogen or oxygen atoms at its end(s) or in its molecular chain. Monovalent organic group refers to, for example, a monovalent group containing a carbon atom. Examples of divalent organic groups include a divalent group obtained by removing one more hydrogen atom from a hydrocarbon group and a carbonyl group (—CO— group). “Hydrocarbon group” refers to a group containing carbon and hydrogen and obtained by removing one hydrogen atom from a molecule.

R¹ is preferably a methyl group.

R² is preferably an alkyl group with one or more and ten or fewer carbon atoms or a phenyl group with at least one of its hydrogen atoms optionally replaced, more preferably an alkyl group with one or more and eight or fewer carbon atoms, o-tolyl group, m-tolyl group, or p-tolyl group. For example, R² is an alkyl group with one or more and eight or fewer carbon atoms or o-tolyl group. An alkyl group may be a linear chain or may have a branched chain.

Preferably, each R³ is independently —NO₂, —O—R³¹, or —CO—R³².

R³¹ is a monovalent organic group, preferably —Cₙ₁H₂ₙ₁₊₁ or —Cₙ₁H₂ₙ₁—OH. For example, R³¹ is —Cₙ₁H₂ₙ₁—OH. In the formulae, each n1 is independently an integer of 1 or greater and 6 or smaller (i.e., from 1 to 6). For example, each n1 is independently 2 or 3, specifically 2.

R³² is a monovalent organic group, preferably an aromatic group. The ring structure in the aromatic group may contain an atom other than a carbon atom, such as an oxygen atom or sulfur atom. The ring structure in the aromatic group may be substituted with one or more substituents. Examples of aromatic groups are as follows. * indicates a binding site.

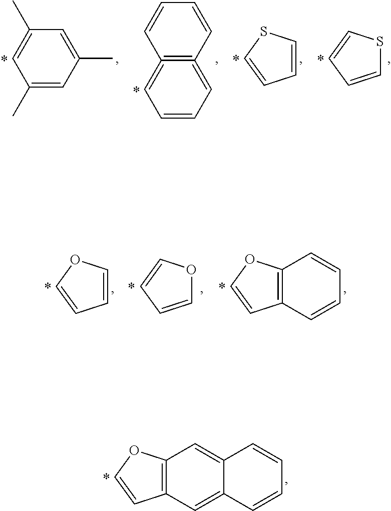

X is preferably a single bond or —CO—.

m is preferably 1.

n is preferably 1.

The oxime ester initiator having a diphenyl sulfide group is preferably represented by the formula below. The symbols are as described above.

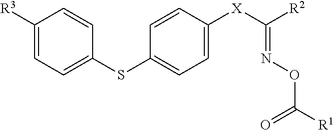

Examples of oxime ester initiators having a diphenyl sulfide group are as follows.

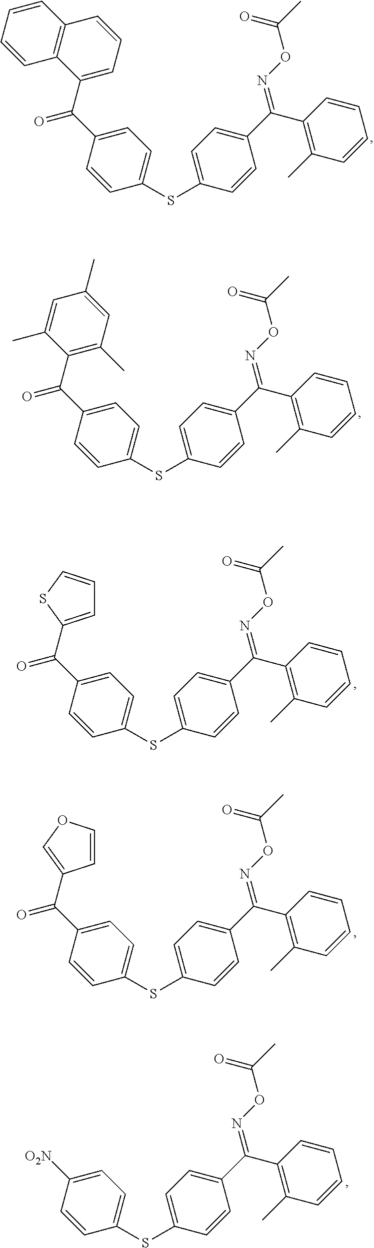 [SMILES: CC(=O)O/N=C(/c1ccc(Sc2ccc(C(=O)c3cccc4ccccc34)cc2)cc1)c1ccccc1C ; CC(=O)O/N=C(/c1ccc(Sc2ccc(C(=O)c3c(C)cc(C)cc3C)cc2)cc1)c1ccccc1C ; CC(=O)O/N=C(/c1ccc(Sc2ccc(C(=O)c3cccs3)cc2)cc1)c1ccccc1C ; CC(=O)O/N=C(/c1ccc(Sc2ccc(C(=O)c3ccoc3)cc2)cc1)c1ccccc1C ; CC(=O)O/N=C(/c1ccc(Sc2ccc([N+](=O)[O-])cc2)cc1)c1ccccc1C]

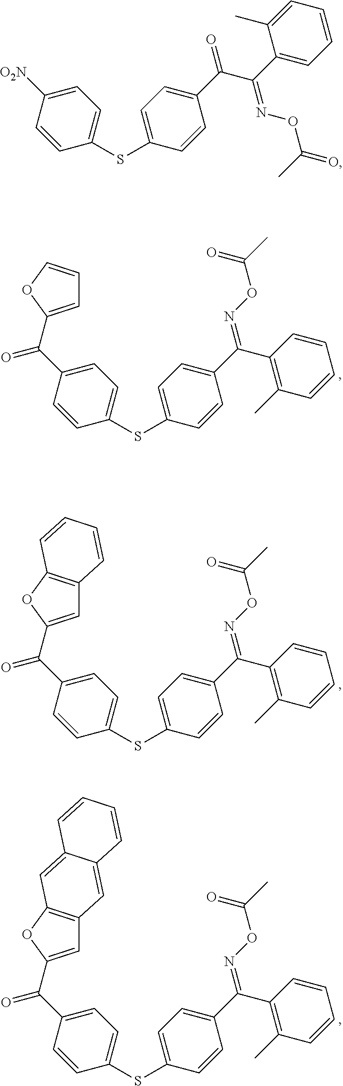 [SMILES: CC(=O)O/N=C(/C(=O)c1ccc(Sc2ccc([N+](=O)[O-])cc2)cc1)c1ccccc1C ; CC(=O)O/N=C(/c1ccc(Sc2ccc(C(=O)c3ccco3)cc2)cc1)c1ccccc1C ; CC(=O)O/N=C(/c1ccc(Sc2ccc(C(=O)c3cc4ccccc4o3)cc2)cc1)c1ccccc1C ; CC(=O)O/N=C(/c1ccc(Sc2ccc(C(=O)c3cc4cc5ccccc5cc4o3)cc2)cc1)c1ccccc1C]

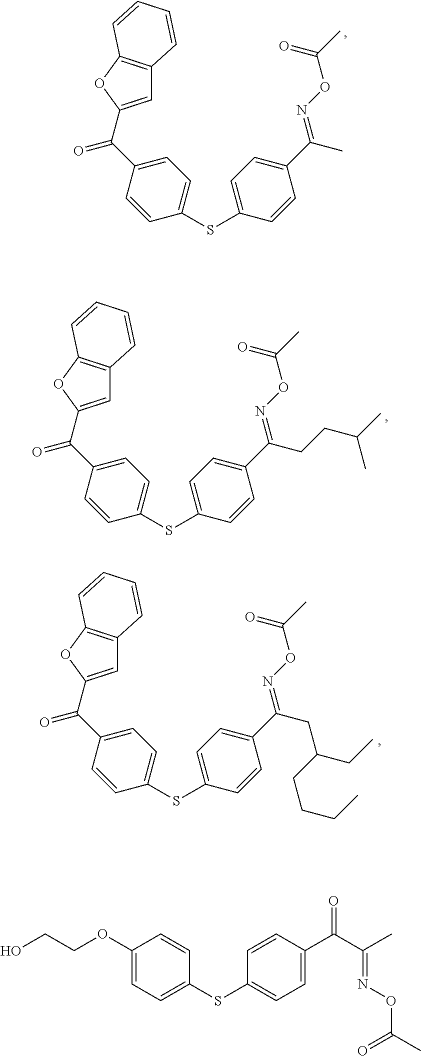 [SMILES: CC(=O)O/N=C(\C)c1ccc(Sc2ccc(C(=O)c3cc4ccccc4o3)cc2)cc1 ; CC(=O)O/N=C(\CCC(C)C)c1ccc(Sc2ccc(C(=O)c3cc4ccccc4o3)cc2)cc1 ; CCCCC(CC)C/C(=N\OC(C)=O)c1ccc(Sc2ccc(C(=O)c3cc4ccccc4o3)cc2)cc1 ; CC(=O)O/N=C(\C)C(=O)c1ccc(Sc2ccc(OCCO)cc2)cc1]

Preferably, R¹ is a methyl group, R² is a methyl group, R³ is —O—CH₂CH₂—OH, X is —CO—, m is 1, and n is 1. In other words, the oxime ester initiator having a diphenyl sulfide group is preferably a compound represented as follows.

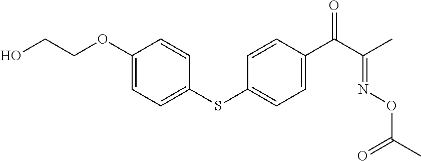 [SMILES: CC(=O)O/N=C(\C)C(=O)c1ccc(Sc2ccc(OCCO)cc2)cc1]

The amount of the oxime ester initiator having a diphenyl sulfide group in relation to the photosensitive resin composition may be 1% by mass or more and may be 2% by mass or more. The amount of the oxime ester initiator having a diphenyl sulfide group in relation to the photosensitive resin composition may be 10% by mass or less and may be 5% by mass or less. In one aspect, the amount of the oxime ester initiator having a diphenyl sulfide group in relation to the photosensitive resin composition is 1% by mass or more and 10% by mass or less (i.e., from 1% by mass to 10% by mass) and may be 2% by mass or more and 5% by mass or less (i.e., from 2% by mass to 5% by mass).

The amount of the oxime ester initiator having a diphenyl sulfide group in relation to the first composition may be 1% by mass or more and may be 3% by mass or more. The amount of the oxime ester initiator having a diphenyl sulfide group in relation to the first composition may be 10% by mass or less and may be 15% by mass or less. In one aspect, the amount of the oxime ester initiator having a diphenyl sulfide group in relation to the first composition may be 1% by mass or more and 15% by mass or less (i.e., from 1% by mass to 15% by mass) and may be 3% by mass or more and 10% by mass or less (i.e., from 3% by mass to 10% by mass).

The amount of the oxime ester initiator having a diphenyl sulfide group in relation to the photopolymerizable monomer may be 5% by mass or more and may be 10% by mass or more. The amount of the oxime ester initiator having a diphenyl sulfide group in relation to the photopolymerizable monomer may be 30% by mass or less and may be 40% by mass or less. In one aspect, the amount of the oxime ester initiator having a diphenyl sulfide group in relation to the photopolymerizable monomer may be 5% by mass or more and 40% by mass or less (i.e., from 5% by mass to 40% by mass) and may be 10% by mass or more and 30% by mass or less (i.e., from 10% by mass to 30% by mass).

When the amount of the oxime ester initiator having a diphenyl sulfide group is too small, the formation of free radicals is low, and the reaction of the photopolymerizable monomer does not proceed smoothly. In that case, furthermore, the thickness, in the direction of irradiation with the active energy radiation, can be small. When this amount is too large, the reaction of the photopolymerizable monomer proceeds readily, and the control of the reaction is difficult.

It should be noted that the oxime ester initiator having a diphenyl sulfide group may be the only initiator, or the oxime ester initiator having a diphenyl sulfide group and a photopolymerization initiator other than an oxime ester initiator having a diphenyl sulfide group may be used together.

### Photopolymerizable Monomer

The photopolymerizable monomer produces monomer radicals by reacting with the photopolymerization initiator. The monomer radicals polymerize to form a polymer.

The photopolymerizable monomer is not limited as long as it has at least one reactive group that undergoes free radical reaction. An example of the free radical reaction group is at least one selected from the group consisting of an acrylamide group, an acryloyl group, a methacryloyl group, an allyl group, a vinyl group, a styryl group, and a mercapto group. The photopolymerizable monomer may have at least one (meth)acryloyl group as the free radical reaction group. “(Meth)acryloyl group” represents an acryloyl group and/or a methacryloyl group.

Examples of photopolymerizable monomers having a (meth)acryloyl group include monofunctional (meth)acrylate monomers, such as stearyl (meth)acrylate, tetrahydrofurfuryl (meth)acrylate, lauryl (meth)acrylate, 2-phenoxyethyl (meth)acrylate, isodecyl (meth)acrylate, isooctyl (meth)acrylate, tridecyl (meth)acrylate, caprolactone (meth)acrylate, and ethoxylated nonylphenol (meth)acrylate; bifunctional (meth)acrylate monomers, such as tripropylene glycol di(meth)acrylate, isocyanuric acid EO-modified diacrylate, 1,3-butanediol di(meth)acrylate, 1,4-butanediol di(meth)acrylate, diethylene glycol di(meth)acrylate, tetraethylene glycol di(meth)acrylate, triethylene glycol di(meth)acrylate, ethoxylated bisphenol A di(meth)acrylate, and propoxylated neopentyl glycol di(meth)acrylate; trifunctional (meth)acrylate monomers, such as glycerol tri(meth)acrylate, trimethylolpropane tri(meth)acrylate, ethoxylated trimethylolpropane tri(meth)acrylate, propoxylated trimethylolpropane tri(meth)acrylate, propoxylated glyceryl tri(meth)acrylate, pentaerythritol tri(meth)acrylate, dipentaerythritol tri(meth)acrylate, ethoxylated pentaerythritol tri(meth)acrylate, tris(2-hydroxyethyl)isocyanurate tri(meth)acrylate, caprolactone-modified tris(2-hydroxyethyl)isocyanurate tri(meth)acrylate, hexanediol tri(meth)acrylate, tripropylene glycol tri(meth)acrylate, trimethylolpropane tri(meth)acrylate, and EO-modified trimethylolpropane tri(meth)acrylate; tetrafunctional (meth)acrylate monomers, such as pentaerythritol tetra(meth)acrylate, dipentaerythritol tetra(meth)acrylate, tripentaerythritol tetra(meth)acrylate, ditrimethylolpropane tetra(meth)acrylate, and ethoxylated pentaerythritol tetra(meth)acrylate; pentafunctional (meth)acrylate monomers, such as dipentaerythritol penta(meth)acrylate, tripentaerythritol penta(meth)acrylate, and dipentaerythritol monohydroxypenta(meth)acrylate; hexafunctional (meth)acrylate monomers, such as dipentaerythritol hexa(meth)acrylate, caprolactone-modified dipentaerythritol hexa(meth)acrylate, and tripentaerythritol hexa(meth)acrylate; and heptafunctional and higher-functionality (meth)acrylate monomers, such as tripentaerythritol hepta(meth)acrylate and tripentaerythritol octa(meth)acrylate.

The amount of the photopolymerizable monomer in relation to the photosensitive resin composition may be 5% by mass or more and may be 10% by mass or more. The amount of the photopolymerizable monomer in relation to the photosensitive resin composition may be 35% by mass or less and may be 25% by mass or less. In one aspect, the amount of the photopolymerizable monomer in relation to the photosensitive resin composition may be 5% by mass or more and 35% by mass or less (i.e., from 5% by mass to 35% by mass) and may be 10% by mass or more and 25% by mass or less (i.e., from 10% by mass to 25% by mass).

The amount of the photopolymerizable monomer in relation to the first composition may be 10% by mass or more and may be 20% by mass or more. The amount of the photopolymerizable monomer in relation to the first composition may be 40% by mass or less and may be 50% by mass or less. In one aspect, the amount of the photopolymerizable monomer in relation to the first composition may be 10% by mass or more and 50% by mass or less (i.e., from 10% by mass to 50% by mass) and may be 20% by mass or more and 40% by mass or less (i.e., from 20% by mass to 40% by mass).

When the amount of the photopolymerizable monomer is too small, the reaction of the photopolymerizable monomer does not proceed smoothly. In that case, furthermore, the thickness, in the direction of irradiation with the active energy radiation, can be small. When the amount of the photopolymerizable monomer is too large, the free radical reaction proceeds readily, and the control of the reaction is difficult.

### Alkali-Soluble Polymer

When the photopolymerizable monomer is caused to polymerize by the active energy radiation, the alkali-soluble polymer present in its vicinity forms a film together with the polymer of the photopolymerizable monomer, forming part of the wiring pattern. As a result of this, the adhesion of the wiring pattern to the insulating sheet can improve. The alkali-soluble polymer, on the other hand, is a polymer that is neutralized by a basic compound and thereby becomes soluble. The alkali-soluble polymer is removed together with materials such as uncured photopolymerizable monomers and the inorganic powder, for example during development treatment using a basic chemical.

The alkali-soluble polymer has at least one acid radical at its side chain. A typical example of an acid radical is a carboxy group. The alkali-soluble polymer contains, for example, a polymeric chain having at least one of a carbon-carbon bond, an ether linkage, a urea linkage, an ester linkage, or a urethane linkage as its backbone. For transparency reasons, the backbone of the alkali-soluble polymer may include a polymeric chain having a carbon-carbon bond.

An alkali-soluble polymer having at least one carboxy group at its side chain and containing, as its backbone, a polymeric chain having a carbon-carbon bond is obtained through, for example, the copolymerization of an ethylenically unsaturated carboxylic acid and an ethylenically unsaturated compound. A typical example of an alkali-soluble polymer is a carboxy-containing acrylic polymer.

Examples of ethylenically unsaturated carboxylic acids include acrylic acid, methacrylic acid, crotonic acid, maleic acid, fumaric acid, itaconic acid, and vinylacetic acid and their dimers and anhydrides.

Examples of ethylenically unsaturated compounds include acrylates, such as methyl acrylate, ethyl acrylate, butyl acrylate, isobutyl acrylate, t-butyl acrylate, 2-ethylhexyl acrylate, lauryl acrylate, and isobornyl acrylate; methacrylates, such as methyl methacrylate, ethyl methacrylate, butyl methacrylate, isobutyl methacrylate, t-butyl methacrylate, 2-ethylhexyl methacrylate, lauryl methacrylate, and isobornyl methacrylate; fumarates, such as monoethyl fumarate; and styrene.

The weight-average molecular weight (Mw) of the alkali-soluble polymer may be 10,000 or more and 50,000 or less (i.e., from 10,000 to 50,000). The acid value of the alkali-soluble polymer may be 30 or more and 150 or less (i.e., from 30 to 150).

The amount of the alkali-soluble polymer in relation to the photosensitive resin composition may be 0.5% by mass or more and may be 2% by mass or more. The amount of the alkali-soluble polymer in relation to the photosensitive resin composition may be 50% by mass or less and may be 40% by mass or less. In one aspect, the amount of the alkali-soluble polymer in relation to the photosensitive resin composition may be 0.5% by mass or more and 50% by mass or less (i.e., from 0.5% by mass to 50% by mass) and may be 2% by mass or more and 40% by mass or less (i.e., from 2% by mass to 40% by mass).

The amount of the alkali-soluble polymer in relation to the first composition may be 40% by mass or more and may be 50% by mass or more. The amount of the alkali-soluble polymer in relation to the first composition may be 80% by mass or less and may be 70% by mass or less. In one aspect, the amount of the alkali-soluble polymer in relation to the first composition may be 40% by mass or more and 80% by mass or less (i.e., from 40% by mass to 80% by mass) and may be 50% by mass or more and 70% by mass or less (i.e., from 50% by mass to 70% by mass).

### Second Composition

A solvent and other additives may be referred to as the second composition.

### Solvent

The photosensitive paste according to the present disclosure may contain a solvent. Examples of solvents include glycol organic solvents, such as ethylene glycol monobutyl ether, ethylene glycol monohexyl ether, ethylene glycol monoethylhexyl ether, propylene glycol monobutyl ether, dipropylene glycol monoethyl ether, dipropylene glycol monobutyl ether, and propylene glycol monophenyl ether. By containing a solvent, the photosensitive paste becomes easier to handle.

The amount of the solvent in relation to the total amount of the inorganic powder and the first composition may be 3% by mass or more and may be 6% by mass or more. The amount of the solvent in relation to the total amount of the inorganic powder and the first composition may be 20% by mass or less and may be 15% by mass or less. In one aspect, the amount of the solvent in relation to the total amount of the inorganic powder and the first composition may be 3% by mass or more and 20% by mass or less (i.e., from 3% by mass to 20% by mass) and may be 6% by mass or more and 15% by mass or less (i.e., from 6% by mass to 15% by mass).

### Other Additives

The photosensitive paste according to the present disclosure may contain various additives. Examples of additives include metal resinates, radical scavengers, sensitizers, defoamers, dispersants, and anti-settling agents.

The photosensitive paste of the present disclosure has a characteristic in which the ratio D/L between thickness D (m) and width L (m) after irradiation with active energy radiation is 0.6 or greater. By virtue of the ratio D/L being a high value, even a wiring pattern with a large thickness and a small width can be formed. With the use of such a wiring pattern, a subminiature inductor component can be manufactured, and the resulting component is suitable for use in, for example, die shrinks. In this context, width L is the difference between the width of an opening 50a in a photomask 50 and the width of a cured portion 21B of a photosensitive paste film 21A formed from the photosensitive paste of the present disclosure when the photomask 50 is formed on the photosensitive paste film 21A and development is performed after irradiation with the active energy radiation. Thickness D is, with regard to a photosensitive paste film formed by applying the photosensitive paste of the present disclosure onto a first surface of a substrate having translucency, the substrate having the first surface and a second surface on the side opposite the first surface, and drying the applied paste, the thickness of a cured portion of the photosensitive paste film formed through irradiation with the active energy radiation in the direction normal to the first surface of the substrate having translucency and subsequent development.

Especially with regard to subminiature inductor components, such as inductor components for which the magnitude of at least one of the width, height, or length of the inductor component 10 is 300 μm or less, there are the goals of reducing the size of wiring, forming wiring with a high aspect ratio, and reducing residue left behind between wiring patterns. The inventors found for the first time that this problem can be solved by a photosensitive paste having a characteristic in which the ratio D/L is 0.6 or greater. The photosensitive paste of the present disclosure has an oxime ester initiator having a diphenyl sulfide group and, by virtue of having this initiator, is able to dramatically solve this problem. The inventors believe that the diphenyl sulfide group is a group that increases photobleachability, which makes it less likely that scattered light in the direction perpendicular to the direction of irradiation with the active energy radiation emanates. To be more exact, the inventors believe that by using an oxime ester initiator having a diphenyl sulfide group, the absorbance of the active energy radiation in the direction of irradiation can be reduced (i.e., transmittance can be increased) with the oxime ester group, and the absorbance of the active energy radiation in the direction perpendicular to the direction of irradiation can be increased (i.e., transmittance can be reduced) with the diphenyl sulfide group at the same time.

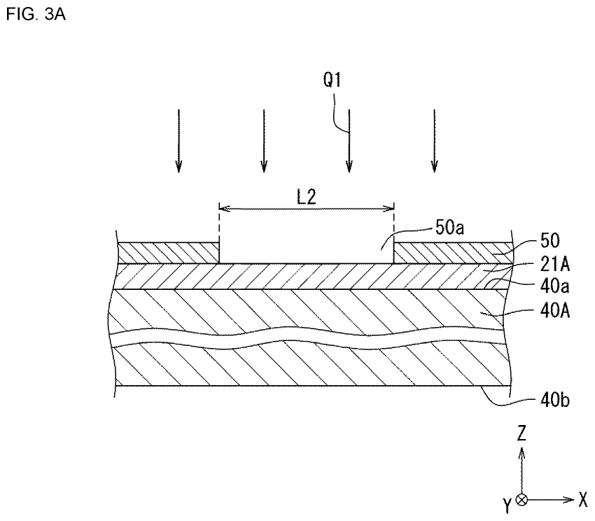

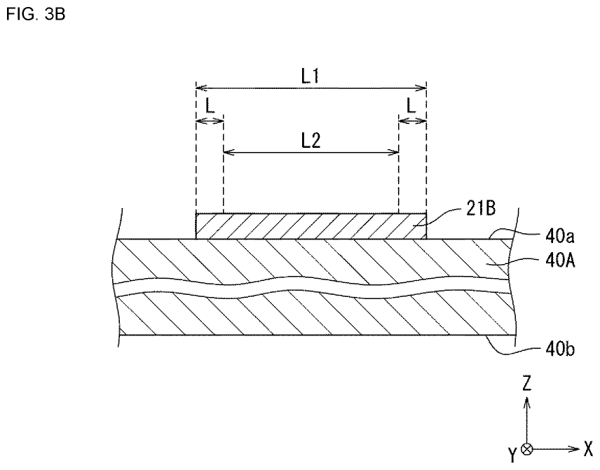

Width L will be specifically described. As illustrated in FIG. 3A, specifically, the photosensitive paste is applied onto a first surface 40a of an insulating layer 40A, such as an alumina substrate, having the first surface 40a and a second surface 40b on the side opposite the first surface 40a. Then the photosensitive paste is dried to form a photosensitive paste film 21A. A photomask 50 having an opening 50a is formed on the surface of the photosensitive paste film 21A opposite the insulating layer 40A. The workpiece is irradiated with active energy radiation Q1 in such a manner that the radiation will be perpendicular to the surface of the photomask 50 opposite the photosensitive paste film 21A. Then an uncured portion of the photosensitive paste film 21A is removed using a solvent, and a cured portion 21B is obtained as illustrated in FIG. 3B. In a cross-section perpendicular to the direction in which the photosensitive paste film 21A extends, the width of the cured portion 21B is defined as L1 μm, and the width of the opening 50a is defined as L2 μm. Width L is the difference between L1 and L2. In other words, width L is a width by which the line has thickened compared with the width L2 μm planned as that of the cured portion. It should be noted that L1 is the maximum width of the cured portion 21B in the cross-section perpendicular to the direction in which the photosensitive paste film 21A extends.

Thickness D will be specifically described. Specifically, the photosensitive paste of the present disclosure is applied onto a first surface of a substrate (e.g., glass, silicon, quartz, or alumina). The photosensitive paste is dried to form a photosensitive paste film with thickness D1. Thickness D1 is, for example, 40 μm. The workpiece is irradiated with active energy radiation in the direction normal to the first surface. Then an uncured portion of the photosensitive paste is removed using a developer to give a cured portion with thickness D. Thickness D is a parameter that represents curability; the greater thickness D is, the higher curability is.

### Method for Forming a Wiring Pattern

A method for forming a wiring pattern will now be described.

The wiring pattern is formed by a method including a step of applying the above photosensitive paste onto an insulating sheet to form a photosensitive paste film, a step of irradiating part of the photosensitive paste film with active energy radiation, and a step of removing an uncured portion of the photosensitive paste film to form a wiring pattern.

### (1) Preparation of an Insulating Sheet

First, an insulating sheet is prepared. The insulating sheet is prepared, for example, as follows. A paste with insulating properties (hereinafter referred to as the insulating paste) is applied to the entire surface on a support film, such as a polyethylene terephthalate film, by screen printing and dried. This cycle of printing and drying is repeated several times as necessary. In such a manner, an insulating sheet having a predetermined thickness (e.g., approximately 100 μm) is obtained.

The insulating paste usually contains an inorganic powder with insulating properties. Typical examples of inorganic powders with insulating properties include a glass powder and a ceramic powder. A glass powder contained in the insulating paste may be SiO₂—K₂O—B₂O₃ glass, which contains SiO₂, K₂O, and B₂O₃ in predetermined proportions. It is also possible to use two or more types of glass powders. The average particle size of the glass powder is not particularly limited. For example, it is 0.5 μm or more and 4.0 μm or less (i.e., from 0.5 μm to 4.0 μm).

A ceramic powder contained in the insulating paste may be a metal oxide and may be aluminum oxide. It is also possible to use two or more types of ceramic powders. The average particle size of the ceramic powder is not particularly limited. For example, it may be 0.1 μm or more and 5.0 μm or less (i.e., from 0.1 μm to 5.0 μm).

Alternatively, the insulating sheet may be prepared by stacking green sheets that have been shaped into sheets in advance.

### (2) Formation of a Photosensitive Paste Film

A photosensitive paste according to the present disclosure is applied onto the insulating sheet by screen printing and dried. Through this, a photosensitive paste film is obtained. The thickness of the photosensitive paste film is not particularly limited. For example, it may be 5 μm or more and 10 μm or less (i.e., from 5 μm to 10 μm).

(3) Irradiation with Active Energy Radiation

A photomask is formed on the photosensitive paste film. The workpiece is irradiated with active energy radiation in such a manner that the radiation will be perpendicular to the surface of the photomask opposite the photosensitive paste film. By the photomask, the active energy radiation is partially blocked. Examples of types of active energy radiation include visible light, ultraviolet radiation, infrared radiation, X-rays, α rays, β rays, γ rays, and electron beams. In particular, the active energy radiation may be ultraviolet radiation and may be ultraviolet radiation having its peak wavelength between 350 nm and 420 nm.

The integrated intensity of the active energy radiation is selected as appropriate, for example according to the type and amount of the photopolymerizable monomer, the amount of the oxime ester initiator having a diphenyl sulfide group, and the thickness of the photosensitive paste film. The integrated intensity of the active energy radiation may be, for example, 100 mJ/cm² or more and 2000 mJ/cm² or less (i.e., from 100 mJ/cm² to 2000 mJ/cm²).

### (4) Removal of an Uncured Portion of the Photosensitive Paste Film

Lastly, an uncured portion of the photosensitive paste film is removed, for example using a solution containing a basic compound. Through this, a wiring pattern made of cured photosensitive paste is formed. By virtue of having this configuration, this method allows a wiring pattern having the desired shape to be formed. This wiring pattern, furthermore, is superior in resolution.

### Method for Manufacturing an Inductor Component

A method for manufacturing an inductor component 10 will now be described.

The inductor component 10 is manufactured by a method including a step of applying the above photosensitive paste onto an insulating sheet to form a photosensitive paste film, a step of irradiating part of the photosensitive paste film with active energy radiation, a step of removing an uncured portion of the photosensitive paste film to form a wiring pattern, a step of placing an insulating sheet on the wiring pattern, and a step of firing the wiring pattern and the insulating sheets to obtain multiple insulating layers 40 as a sintered form of multiple insulating sheets and a coil wire 2 as a sintered form of the wiring pattern (cured photosensitive paste).

The steps up to the formation of a wiring pattern are performed in the same manner as (1) the preparation of an insulating sheet, (2) the formation of a photosensitive paste film, (3) irradiation with active energy radiation, and (4) the removal of an uncured portion of the photosensitive paste film described above. In the method for forming an inductor component 10, this series of steps (1) to (4) up to the formation of a wiring pattern is performed multiple cycles.

In the second cycle, (1) the preparation of an insulating sheet is performed as described above on the wiring pattern formed in the first cycle, rather than on the support film. As a result of this, a second-layer insulating sheet is placed. At a predetermined position of this second-layer insulating sheet, a via hole 3 is created by irradiation with laser light.

Then (2) the formation of a photosensitive paste film, (3) irradiation with active energy radiation, and (4) the removal of an uncured portion of the photosensitive paste film are performed again, and thereby a second-layer wiring pattern is formed.

(1) The preparation of an insulating sheet, the creation of a via hole 3, (2) the formation of a photosensitive paste film, (3) irradiation with active energy radiation, and (4) the removal of an uncured portion of the photosensitive paste film are repeated until the desired number of layers are obtained.

Lastly, (1) the preparation of an insulating sheet is repeated as many times as needed, and thereby insulating sheets are formed on the top-layer wiring pattern. Through this, a multilayer structure is obtained that includes multiple layers of insulating sheets and wiring patterns and in which the wiring patterns are coupled together between layers by via wires with the via holes 3 interposed therebetween.

The resulting multilayer structure is divided into chips with a dicer. Thereafter, the support film used in the preparation of the first-layer insulating sheet is removed.

### (5) Firing

Subsequently, the chip-shaped multilayer structures are fired. Through this firing, the multiple wiring patterns are sintered, and thereby multiple coil wires 2 are formed. At the same time, a coil 5 is formed in which these multiple coil wires 2 are electrically coupled together. The multiple insulating sheets, furthermore, are sintered, and thereby a body 4 including multiple insulating layers 40 is formed. The firing temperature is not particularly limited and can be selected as appropriate considering factors such as the types of materials used. By virtue of having this configuration, this method allows an inductor component having high-accuracy inner wiring to be obtained.

After firing, a first outer electrode 6a and a second outer electrode 6b are formed on the outside of the body 4. Through these, an inductor component 10 as illustrated in FIG. 1 is obtained.

Moreover, a plating layer having a single-layer or multilayer structure may be formed on the outer surface of the first and second outer electrodes 6a and 6b, for example by electrolytic plating or electroless plating.

In addition, the ratio between the inorganic powder, the photopolymerizable monomer, the alkali-soluble polymer, and the oxime ester initiator having a diphenyl sulfide group in the photosensitive paste and that between the inorganic powder, the photopolymerizable monomer, the alkali-soluble polymer, and the oxime ester initiator having a diphenyl sulfide group in the cured portion are equal.

It should be noted that the present disclosure is not limited to the above embodiments, and modifications are possible without departing from the spirit of the present disclosure.

### EXAMPLES

The present disclosure will be described more specifically through the following examples, but the present disclosure is not limited to these examples.

### Example 1

A photosensitive paste was formed by sufficiently mixing the following inorganic powder and photosensitive resin composition together using a three-roll mill.
Inorganic powder: A Ag powder (D50: 4 μm), 75 parts by mass
The first resin composition and the second composition: 25 parts by mass

| | | | Amount in the |
|---|---|---|---|
| | | | photosensitive |
| | Ingredients | | resin composition |
| First | Photopolymerizable monomer | A polyfunctional | 18 parts by mass |
| composition | | acrylate monomer | |
| | Alkali-soluble polymer | An acrylic polymer | 39 parts by mass |
| | | having a carboxy group | |
| | | at its side chain | |
| | Oxime ester initiator having | Compound 1 | 4 parts by mass |
| | a diphenyl sulfide group | | |
| Second | Solvent | A glycol organic solvent | 38 parts by mass |
| composition | Defoamer | | 1 part by mass |

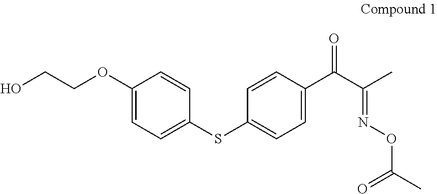 [SMILES: CC(=O)O/N=C(\C)C(=O)c1ccc(Sc2ccc(OCCO)cc2)cc1]

### Comparative Example 1

A photosensitive paste was formed by performing the same as in Example 1, except that compound 2 below was used instead of the oxime ester initiator having a diphenyl sulfide group.

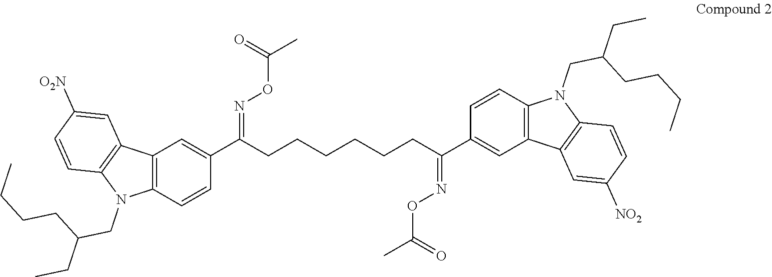 [SMILES: CCCCC(CC)Cn1c2ccc(/C(CCCCCC/C(=N\OC(C)=O)c3ccc4c(c3)c3cc([N+](=O)[O-])ccc3n4CC(CC)CCCC)=N/OC(C)=O)cc2c2cc([N+](=O)[O-])ccc21]

### Comparative Example 2

A photosensitive paste was formed by performing the same as in Example 1, except that compound 3 below was used instead of the oxime ester initiator having a diphenyl sulfide group.

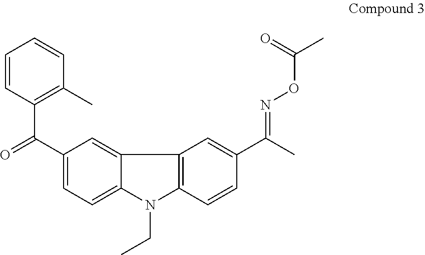 [SMILES: CCn1c2ccc(C(=O)c3ccccc3C)cc2c2cc(/C(C)=N/OC(C)=O)ccc21]

### Measurement of Width L

The photosensitive paste was applied onto an insulating layer 40A that was an alumina substrate with a thickness of 1 mm, which was an insulating layer, by screen printing. Then the workpiece was dried for 30 minutes at 60° C. to form a photosensitive paste film 21A with a film thickness of 8 μm. A photomask 50 was formed on the photosensitive paste film 21A. The photomask 50 had linear openings 50a with a width of m, and the distance between the linear openings 50a was 45 μm. The workpiece was irradiated with active energy radiation Q1 (wavelengths, 365 to 405 nm; light source, an ultrahigh-pressure mercury lamp manufactured by Ushio Inc.) under the condition of an integrated intensity of 250 mJ/cm² in such a manner that the radiation would be perpendicular to the surface of the photomask 50 opposite the photosensitive paste film 21A. Lastly, an uncured portion of the photosensitive paste film 21A was removed using an aqueous solution of triethanolamine to give a cured portion 21B. With the width of the cured portion 21B as L1 μm and the width of the openings 50a, 15 μm, as L2 μm, width L, which was the difference between L1 and L2, was determined.

### Measurement of Thickness D

The photosensitive paste was applied onto a first surface of an insulating layer having translucency that was a quartz substrate with a thickness of 1 μmm, which was an insulating layer, by screen printing. Then the workpiece was dried for 30 minutes at 60° C. to form a photosensitive paste film whose thickness D1 was 30 μm. After the formation of the photosensitive paste film, the workpiece was irradiated with active energy radiation (wavelengths, 365 to 405 nm; light source, an ultrahigh-pressure mercury lamp manufactured by Ushio Inc.) in the direction normal to the first surface of the insulating layer under the condition of an integrated intensity of 250 mJ/cm². Lastly, an uncured portion of the photosensitive paste film was removed using an aqueous solution of triethanolamine to give a cured portion of the photosensitive paste film. The thickness D of this cured portion was measured with Optelics (manufactured by Lasertec Corporation).

From these thickness D μm and width L μm, the ratio D/L was determined. The results are presented in Table 2.

| | | Main | Irradiation intensity | Width | Thickness | Ratio |
|---|---|---|---|---|---|---|
| | Initiator | backbone | (mJ/cm²) | L (μm) | D (μm) | D/L |
| Example 1 | Compound | Diphenyl | 250 | 16 | 10 | 0.63 |
| | 1 | sulfide group | | | | |
| Comparative | Compound | Carbazole | 250 | 32 | 8 | 0.25 |
| Example 1 | 2 | group | | | | |
| Comparative | Compound | Carbazole | 250 | 18 | 8 | 0.44 |
| Example 2 | 3 | group | | | | |

As shown in Table 2, in Example 1, in which an oxime ester initiator having a diphenyl sulfide group was used, the resulting ratio D/L was greater than 0.6. By contrast, in Comparative Example 1, in which the initiator had a carbazole group, the resulting ratio D/L was 0.25. In Comparative Example 2, in which the initiator had a carbazole group, the resulting ratio D/L was 0.44. With the use of an oxime ester initiator having a diphenyl sulfide group, therefore, the spread of active energy radiation in the direction perpendicular to the direction of irradiation with the active energy radiation was reduced, and, furthermore, free radicals with a great spread of the active energy radiation in the direction of irradiation with the active energy radiation were formed.

The present disclosure includes the following aspects.

<1> A photosensitive paste containing an inorganic powder; a photopolymerizable monomer; an alkali-soluble polymer; and an oxime ester initiator having a diphenyl sulfide group.

<2> The photosensitive paste according to <1>, wherein the inorganic powder has a conductive powder.

<3> The photosensitive paste according to <1> or <2>, wherein the inorganic powder has Ag.

<4> The photosensitive paste according to <3>, wherein a D50 of the Ag is 5.0 μm or less.

<5> The photosensitive paste according to any one of <1> to <4>, wherein the oxime ester initiator has an ═N—O—CO—R¹ group, where R¹ is an alkyl group with one or more and three or fewer carbons.

<6> The photosensitive paste according to any one of <1> to <5>, wherein the oxime ester initiator is represented by formula (1):

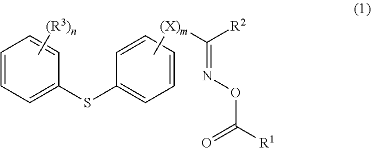

where:
R¹ is an alkyl group with one or more and three or fewer carbon atoms;
R² is a monovalent organic group;
each R³ is independently a monovalent organic group;
each X is independently a divalent organic group;
m is an integer of 1 or greater and 5 or smaller (i.e., from 1 to 5); and
n is an integer of 0 or greater and 5 or smaller (i.e., from 0 to 5).

<7> The photosensitive paste according to <6>, wherein:
R¹ is a methyl group;
R² is a methyl group;
R³ is —O—CH₂CH₂—OH;
X is —CO—;
m is 1; and
n is 1.

<8> The photosensitive paste according to any one of <1> to <7>, wherein: the photosensitive paste has a characteristic in which a ratio D/L between thickness D μm and width L μm after irradiation with active energy radiation is 0.6 or greater; the width L is a difference between a width of an opening in a photomask and a width of a cured portion of a photosensitive paste film formed from the photosensitive paste according to <1> when the photomask is formed on the photosensitive paste film and development is performed after irradiation with the active energy radiation; and the thickness D is, with regard to a photosensitive paste film formed by applying the photosensitive paste according to <1> onto a first surface of a substrate having translucency, the substrate having the first surface and a second surface on a side opposite the first surface, and drying the applied paste, a thickness of a cured portion of the photosensitive paste film formed through irradiation with the active energy radiation in a direction normal to the first surface of the substrate having translucency and subsequent development.

<9> The photosensitive paste according to any one of <1> to <8>, further having an organic solvent.

<10> A method for forming a wiring pattern, the method including a step of applying the photosensitive paste according to any one of <2> to <9> onto an insulating sheet to form a photosensitive paste film; a step of irradiating part of the photosensitive paste film with active energy radiation; and a step of removing an uncured portion of the photosensitive paste film to form a wiring pattern.

<11> A method for manufacturing an electronic component, the method including a step of applying the photosensitive paste according to any one of <2> to <9> onto an insulating sheet to form a photosensitive paste film; a step of irradiating part of the photosensitive paste film with active energy radiation; a step of removing an uncured portion of the photosensitive paste film to form a wiring pattern; a step of placing an insulating sheet on the wiring pattern; and a step of firing the wiring pattern and the insulating sheets to obtain multiple insulating layers as a sintered form of the multiple insulating sheets and inner wiring as a sintered form of the wiring pattern.

<12> An electronic component including a body including multiple insulating layers; and inner wiring disposed inside the body as a sintered form of the photosensitive paste according to any one of <2> to <9> that has been cured.

What is claimed is:

1. A photosensitive paste comprising:
an inorganic powder;
a photopolymerizable monomer;
an alkali-soluble polymer; and
an oxime ester initiator having a diphenyl sulfide group.

2. The photosensitive paste according to claim 1, wherein:
the inorganic powder has a conductive powder.

3. The photosensitive paste according to claim 1, wherein:
the inorganic powder has Ag.

4. The photosensitive paste according to claim 3, wherein:
a D50 of the Ag is 5.0 μm or less.

5. The photosensitive paste according to claim 1, wherein:
the oxime ester initiator has an ═N—O—CO—R¹ group, where R¹ is an alkyl group with from one to three carbons.

6. The photosensitive paste according to claim 1, wherein:
the oxime ester initiator is represented by formula (1): 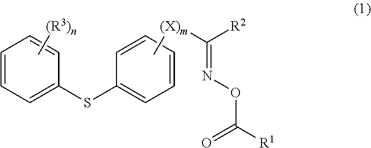
where:
R¹ is an alkyl group with from one to three carbon atoms;
R² is a monovalent organic group;
each R³ is independently a monovalent organic group;
each X is independently a divalent organic group;
m is an integer of from 1 to 5; and
n is an integer of from 0 to 5.

7. The photosensitive paste according to claim 6, wherein:
R¹ is a methyl group;
R² is a methyl group;
R³ is —O—CH₂CH₂—OH;
X is —CO—;
m is 1; and
n is 1.

8. The photosensitive paste according to claim 1, wherein:
the photosensitive paste has a characteristic in which a ratio D/L between thickness D μm and width L μm after irradiation with active energy radiation is 0.6 or greater;
the width L is a difference between a width of an opening in a photomask and a width of a cured portion of a photosensitive paste film made by curing the photosensitive paste when the photomask is on the photosensitive paste film and development is performed after irradiation with the active energy radiation; and
the thickness D is, with regard to a photosensitive paste film made by applying the photosensitive paste onto a first surface of a substrate having translucency, the substrate having the first surface and a second surface on a side opposite the first surface, and drying the applied paste, a thickness of a cured portion of the photosensitive paste film which is cured through irradiation with the active energy radiation in a direction normal to the first surface of the substrate having translucency and subsequent development.

9. The photosensitive paste according to claim 1, further comprising:
an organic solvent.

10. A method for forming a wiring pattern, the method comprising:
applying the photosensitive paste according to claim 2 onto an insulating sheet to form a photosensitive paste film;
irradiating part of the photosensitive paste film with active energy radiation; and
removing an uncured portion of the photosensitive paste film to form a wiring pattern.

11. A method for manufacturing an electronic component, the method comprising:
applying the photosensitive paste according to claim 2 onto an insulating sheet to form a photosensitive paste film;
irradiating part of the photosensitive paste film with active energy radiation;
removing an uncured portion of the photosensitive paste film to form a wiring pattern;
placing another insulating sheet on the wiring pattern; and
firing the wiring pattern and the insulating sheets to sinter the wiring pattern to create a sintered wiring pattern and to sinter the insulating sheets to create sintered insulating sheets.

12. An electronic component comprising:
a body including a plurality of insulating layers; and
inner wiring inside the body, the inner wiring being made of the photosensitive paste according to claim 2 that has been sintered and cured.

13. The photosensitive paste according to claim 2, wherein:
the inorganic powder has Ag.

14. The photosensitive paste according to claim 13, wherein:
A D50 of the Ag is 5.0 μm or less.

15. The photosensitive paste according to claim 2, wherein:
the oxime ester initiator has an ═N—O—CO—R¹ group, where R¹ is an alkyl group with from one to three carbons.

16. The photosensitive paste according to claim 2, wherein:
the oxime ester initiator is represented by formula (1): 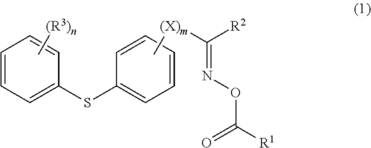
where:
R¹ is an alkyl group with from one to three carbon atoms;
R² is a monovalent organic group;
each R³ is independently a monovalent organic group;
each X is independently a divalent organic group;
m is an integer of from 1 to 5; and
n is an integer of from 0 to 5.

17. The photosensitive paste according to claim 16, wherein:
R¹ is a methyl group;
R² is a methyl group;
R³ is —O—CH₂CH₂—OH;
X is —CO—;
m is 1; and
n is 1.

18. The photosensitive paste according to claim 2, further comprising:
An organic solvent.
